(19) United States
(12) Patent Application Publication
(10) Pub. No.: US 2004/0178425 A1
(43) Pub. Date: Sep. 16, 2004

(54) Semiconductor device having fuse

(75) Inventor: Hisayuki Kato, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/649,737

(22) Filed: Aug. 28, 2003

(30) Foreign Application Priority Data
Mar. 14, 2003 (JP) 2003-069420(P)

(51) Int. Cl. H01L 27/10

(52) U.S. Cl. 257/209; 257/665

(57) ABSTRACT

An object of the present invention is to provide a semiconductor device including a fuse that can easily be blown by a laser beam and free from a problem of oxidation proceeding from a laser-beam blown portion. In order to accomplish this object, a semiconductor device formed on a substrate includes an interconnection line formed on the substrate and provided to structure a prescribed circuit and a fuse that is incorporated into the interconnection line and can be blown by a laser beam. The fuse and a connection portion electrically connected to the fuse at the interconnection line are formed from different metal materials.

### BACKGROUND OF THE INVENTION

1. Field of the Invention

The present invention generally relates to a semiconductor device having fuse. More particularly, the present invention relates to a semiconductor device including a circuit provided with a fuse selectively blown by laser beam to change a circuit structure.

2. Description of the Background Art

A fuse is utilized in a semiconductor device such as an integrated circuit. In particular, a fuse is used in a memory device as an element changing a circuit structure included therein. In changing the circuit structure, the above-mentioned fuse is selectively melted and cut by a laser beam, for example.

Among other semiconductor devices, a DRAM (Dynamic Random Access Memory) includes a spare redundant memory. When an inspection of the DRAM determines that a memory to be operated is defective, any of the spare redundant memories is instead operated. For this purpose, a fuse is selectively blown by a laser beam, as described above.

In the above laser-beam irradiation, the fuse may not always be blown as expected. In addition, other portions of the semiconductor device may adversely be affected. Therefore, proposals have been made to solve these problems (see e.g., Japanese Patent Laying-Open Nos. 2000-311947, 2001-44281, 10-321726, and 9-17877). Following these proposals, a fuse blowing has been performed and a semiconductor device has been repaired.

Forming a fuse from copper has the advantage that a selective blowing of one fuse by a laser beam can easily be performed. This is because a portion to be irradiated with the laser beam can be flat in this case and thus, a focusing can easily be obtained. Copper, however, oxidizes fast. Therefore, oxidation proceeds fast starting from the laser-beam blown portion. Furthermore, a connection portion of an interconnection line is formed from copper since copper is of low resistance. Therefore, once the laser-beam blown portion is oxidized and the oxidation proceeds to the connection portion, an interconnection line resistance is developed, or the circuit performance or a reliability of the interconnection line is adversely affected. Therefore, there is a need for a semiconductor device including a fuse that can easily be blown by a laser beam and free from the problem of oxidation proceeding from the blown portion.

### SUMMARY OF THE INVENTION

An object of the present invention is to provide a semiconductor device including a fuse that can easily be blown by a laser beam and free from a problem of oxidation proceeding from a laser-beam blown portion.

A semiconductor device in accordance with the present invention is formed on a substrate. The semiconductor device includes an interconnection line formed on the above-mentioned substrate and provided to structure a prescribed circuit, and a fuse incorporated into the interconnection line. The fuse and a connection portion of the interconnection line that is electrically connected to the fuse are formed from different metals.

A laser beam blows the fuse. Even if the fuse is formed of a metal allowing oxidation starting from a blown portion of the fuse to proceed fast under a prescribed environment, another metal that can prevent the oxidation proceeding can be provided at the connection portion of the interconnection line that is connected to the fuse as described above. As a result, a prevention of the oxidation proceeding to the interconnection line can be achieved. Accordingly, an interconnection line resistance is not developed. Consequently, the circuit performance or the reliability of the interconnection line are not adversely affected. The above-mentioned “prescribed environment” typically includes a high-temperature heating environment in a semiconductor device manufacturing process and an environment where a semiconductor device is used as a product, however, it may include any type of environment.

Another semiconductor device in accordance with the present invention is formed on a substrate. The semiconductor device includes an interconnection line formed on the above-mentioned substrate and provided to structure a prescribed circuit, and a fuse incorporated into the interconnection line. The fuse has its width configured to be gradually reduced from its end toward its intermediate portion.

Because of this configuration, simply blowing a portion corresponding to any of the widths is sufficient. Therefore, a preliminary set-up of a blowing condition can significantly be easier. As a result, the semiconductor device can be repaired by a fuse blowing at higher rates. Consequently, a manufacturing yield of the semiconductor device can be enhanced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a fuse of a semiconductor device in accordance with a first embodiment of the present invention.

FIG. 2 is a cross-sectional view cut along a line II-II in FIG. 1.

FIG. 3 is a cross-sectional view cut along a line III-III in FIG. 1.

FIG. 4 is a plan view showing a fuse of a semiconductor device in accordance with a second embodiment of the present invention.

FIG. 5 is a cross-sectional view cut along a line V-V in FIG. 4.

FIG. 6 is a plan view showing an antireflection layer.

FIG. 7 is a plan view showing a fuse of a semiconductor device in accordance with a third embodiment of the present invention.

FIG. 8 is a cross-sectional view cut along a line VIII-VIII in FIG. 7.

FIG. 9 is a plan view showing a fuse of a semiconductor device in accordance with a fourth embodiment of the present invention.

### DESCRIPTION OF THE PREFERRED EMBODIMENTS

Each embodiment of the present invention will now be described with reference to the drawings.

### First Embodiment

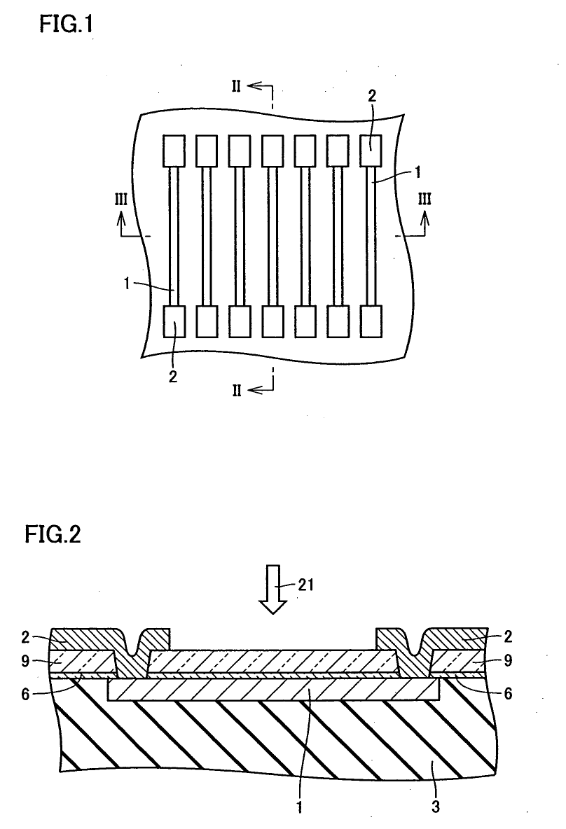

In FIG. 1, a semiconductor device is provided at a substrate (not shown). The semiconductor device includes a plurality of semiconductor elements (not shown) formed at the substrate. A semiconductor substrate such as a silicon substrate is typically employed as the substrate, however, it is not limited to the semiconductor substrate as long as it is a substrate. In addition, the semiconductor element may be formed at a semiconductor film on the substrate, rather than the substrate surface layer. A redundant semiconductor element deployed as a spare is included in these semiconductor elements. An interconnection line includes these semiconductor elements to form a prescribed circuit (not shown). A fuse is incorporated into this circuit.

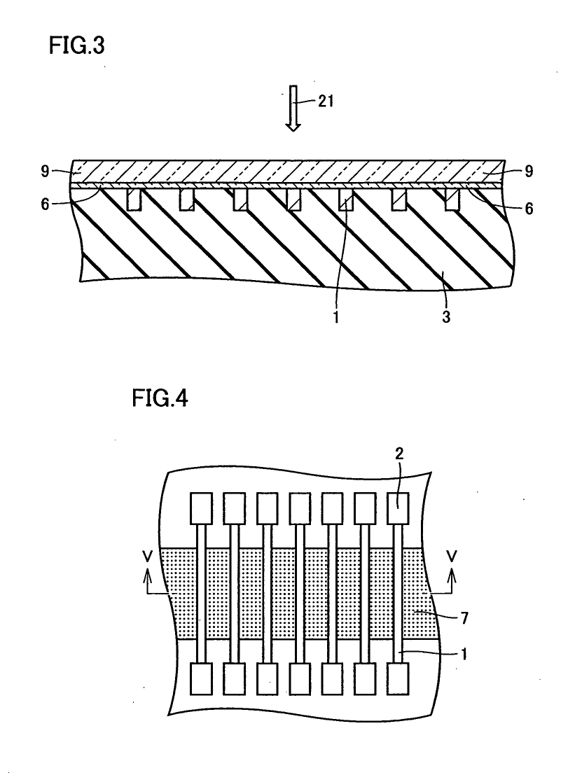

A plurality of parallel fuses 1 incorporated into the above-mentioned circuit are embedded in an insulator film 3 and formed of copper. A connection portion 2 of the interconnection line that is connected to fuse 1 is formed of aluminum. As shown in FIG. 2, i.e., a cross-sectional view cut along a line II-II in FIG. 1, connection portion 2 of the interconnection line that is formed of aluminum contacts fuse 1 from above and is electrically connected to fuse 1. Fuse 1 is covered by a passivation film 6 such as SiN. On passivation film 6, an insulator film 9 such as SiO₂ is provided. FIG. 3 is a cross-sectional view cut along a line III-III in FIG. 1. A surface of the copper forming fuse 1 is flush with a surface of insulator film 3. As shown in FIG. 3, a laser beam 21 selects and irradiates one of the plurality of fuses to blow the fuse.

The laser beam is diaphragmed by an optical system including a lens, and adjusted such that an energy density is high at selected fuse 1. Accordingly, it is desired that the surface of the copper layer forming the fuse is flush with the surface of insulator layer 3 in which the copper layer is embedded. If this is achieved, passivation film 6 can also have a flat surface. When passivation film 6 is flat, a high energy density portion can stably be formed at the selected fuse by the laser beam, thereby an ensured blowing can be achieved.

In order to ensure the above-described flatness, the copper is formed at insulator layer 3 by a damascene process. Subsequently, a CMP (Chemical Mechanical Polishing) process is performed to ensure that insulator film 3 is flush with copper layer 1. As a result, a flatness of passivation film 6 deposited thereon is ensured.

The above copper layer forming fuse 1 facilitates achievement of the above-described flatness. When the copper layer is selected, irradiated, and blown by laser beam 21, however, the blown portion may be oxidized, and the oxidation may proceed fast towards an end during a post-process or the like. Eventually, the oxidation may proceed to the interconnection line. In the present embodiment, however, connection portion 2 at which the interconnection line is connected to the fuse is formed of aluminum as shown in FIG. 2. Therefore, the oxidation proceeding as described above can be prevented.

As described above, in the present embodiment, the flatness is ensured by the copper layer forming the fuse. In addition, the connection portion of the interconnection line that directly contacts the fuse is formed of aluminum. Therefore, it is possible to prevent the proceeding of oxidation from the blown portion to the interconnection line, for example when the semiconductor device is heated to a high temperature in a post-process or while the semiconductor device is being utilized. As a result, a reliability of the selective blowing of the fuse by the laser beam can be improved. Consequently, the semiconductor device can be repaired by the fuse blowing at higher rates.

In the present embodiment, any combination of metals may be employed as long as an oxidation speed of a metal forming the fuse is faster than that of a metal forming the connection portion of the interconnection line during a semiconductor manufacturing process or a use of the semiconductor device.

### Second Embodiment

With reference to FIG. 4, the present embodiment is characterized in that an antireflection layer 7 is provided below fuse 1, i.e., at a layer close to a substrate. Fuse 1 formed from a copper layer and connection portion 2 of an interconnection line that is formed of aluminum are built as described in the first embodiment.

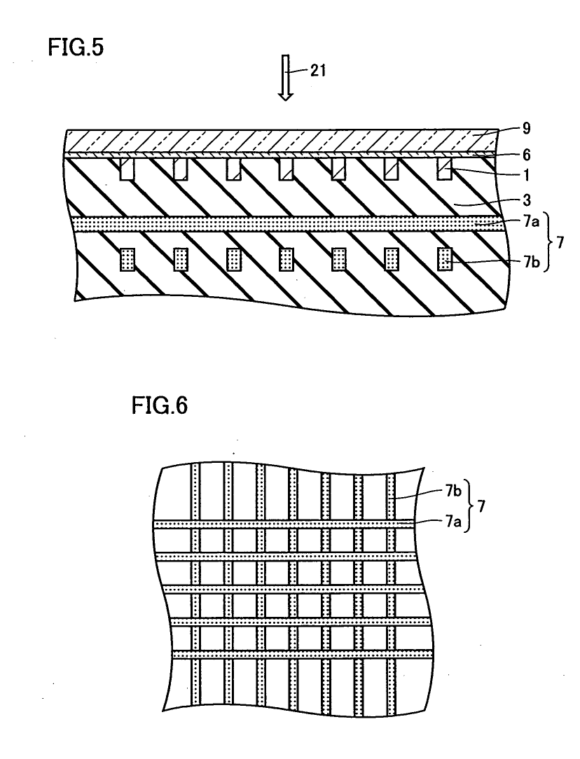

FIG. 5 is a cross-sectional view cut along a line V-V in FIG. 4. FIG. 6 is a plan view showing the antireflection layer provided below the fuse. This antireflection layer includes a first antireflection layer having a plurality of metal bands 7b extending in a direction in which fuse 1 extends, and a second antireflection layer having a plurality of metal bands 7a extending in a direction that crosses the plurality of metal bands 7b. Of course, a layer at which metal band 7a is provided and a layer at which metal band 7b is provided (height positions) are different. Metal band 7a and metal band 7b cross each other desirably at a right angle. The parallel metal bands desirably occupy at most 50% of the layer at which they are provided.

For the above-described antireflection layer, an antireflection layer structure has been described where two antireflection layers with band-like metal lines arranged in parallel cross each other in a plan view. The antireflection layer, however, may have any structure as long as multiple reflection can be prevented by preventing reflection.

Antireflection layer 7 formed by parallel metal bands as described above can scatter laser beam 21 that has irradiated the fuse and passed therethrough. Antireflection layer 7 can also attenuate excessive light. Consequently, it is possible to prevent a formation of a big hole as a result of multiple reflection of the laser beam at a layer (not shown) below the fuse. Here, a big hole is a large-sized blown portion. Its size may be so large as to blow a fuse next to the selected fuse.

As in the present embodiment, through the provision of the antireflection layer below the fuse, the formation of the big hole can be prevented. Moreover, a reliability of a repair of the semiconductor device by a fuse blowing can be improved.

### Third Embodiment

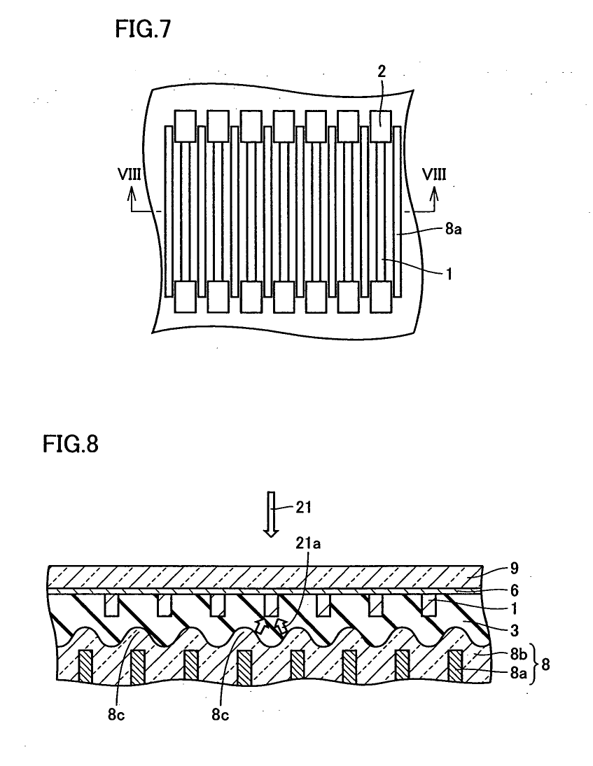

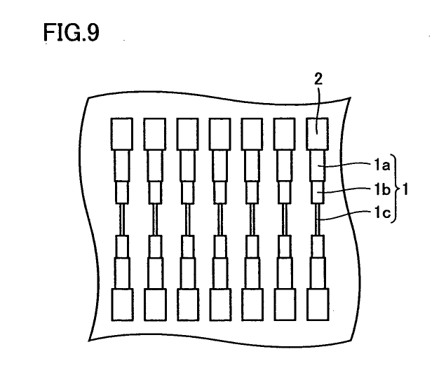

FIG. 7 is a plan view showing a fuse of a semiconductor device in accordance with a third embodiment of the present invention. FIG. 8 is a cross-sectional view cut along a line VIII-VIII in FIG. 7. The present embodiment is characterized in that a reflection layer 8 is provided below fuse 1. Fuse 1 formed from a copper layer and connection portion 2 of an interconnection line that is formed of aluminum are built as described in the first embodiment.

In the present embodiment, reflection layer 8 includes a dummy metal line 8a provided between fuses in a plan view and an HDP (High Density Plasma) film 8b formed to cover the dummy metal line. HDP film 8b has a depression and a protrusion because of an existence of dummy metal line 8a. HDP film 8b has the depression right below the fuse. On the opposite sides of the depression, HDP film 8b has protruded top portions 8c. The HDP film may be any type of transparent resin film.

Laser beam that has passed through the fuse or the like, mainly, a space between fuses is reflected by this HDP film such that the laser beam converges at fuse 1 provided between top portions 8c. As a result, the laser light passed though the fuse layer does not provide multiple reflection below the fuse. Therefore, a formation of a big hole can be prevented. In addition, the laser beam reflected as reflection light 21a irradiates the selected fuse from below the fuse. This enables more reliable blowing of the selected fuse.

The above first to third embodiments illustrate a fuse with a constant width. The width of the fuse in the first to third embodiments, however, may have more than one size.

### Fourth Embodiment

With reference to FIG. 9, the present embodiment provides a fuse having a width gradually reduced from an end toward an intermediate portion of the fuse. More specifically, the present embodiment is characterized in that the fuse has at least three different widths from the end toward the intermediate portion. Fuse 1 formed from a copper layer has portions of at least three different widths 1a, 1b, and 1c, while connection portion 2 of an interconnection line that is formed of aluminum is built as described in the first embodiment.

As described above, through the formation of the fuse having at least three different widths from its end toward its intermediate portion, a condition preliminarily set up for a laser-beam blowing does not have to be restricted to a condition for one width only. In other words, blowing only one of at least three portions different in width is required. Therefore, the preliminary set-up of a blowing condition can significantly be easier. As a result, the semiconductor device can be repaired by the fuse blowing at higher rates. Consequently, a manufacturing yield of the semiconductor device can be enhanced.

The following must be added to the above embodiments.

In the above embodiments, the fuse is formed of copper, and the connection portion of the interconnection line is formed of aluminum. A combination of metals, however, is not limited to the above combination. The fuse may be formed of copper and the interconnection line's connection portion may be formed of silver or the like. In addition, in the broadest sense, any combination of metals may be employed as long as an oxidation speed of a metal forming a fuse is, under any environments, faster than that of a metal forming a connection portion of an interconnection line.

In the above embodiments, the antireflection layer or the reflection film is provided when the fuse has a constant width. The present invention, however, is not limited to the above example. The antireflection layer or the reflection film may be provided even when the fuse has more than one width.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device formed on a substrate, comprising:
an interconnection line formed on said substrate and provided to structure a prescribed circuit; and
a fuse incorporated into said interconnection line,
said fuse and a connection portion of said interconnection line electrically connected to the fuse being formed of different metals.

2. The semiconductor device according to claim 1, wherein
an oxidation speed of the metal forming said fuse is faster than an oxidation speed of the metal forming the connection portion of said interconnection line.

3. The semiconductor device according to claim 1, wherein
said fuse is formed of a copper metal, and
the connection portion of said interconnection line is formed of an aluminum metal.

4. The semiconductor device according to claim 3, wherein
said fuse is formed of the copper metal formed in a damascene process and planarized by a CMP (Chemical Mechanical Polishing) process.

5. The semiconductor device according to claim 1, wherein
said interconnection line is formed as a multilayer interconnection line,
said fuse is provided at a same layer as one layer of the multilayer interconnection line, and
an antireflection layer is provided closer to said substrate than a layer of said fuse is.

6. The semiconductor device according to claim 5, wherein
said antireflection layer includes a first antireflection layer extending in a direction of a length of said fuse, and a second antireflection layer extending in a direction traversing the first antireflection layer.

7. The semiconductor device according to claim 1, wherein
said interconnection line is formed as a multilayer interconnection line,
said fuse is provided at a same layer as one layer of the multilayer interconnection line, and
a reflection layer is provided closer to said substrate than a layer of said fuse is.

8. The semiconductor device according to claim 7, wherein
said reflection layer includes a dummy metal line provided between said fuses in a planar view and a transparent resin film covering the dummy metal line, said transparent resin film forming a recessed and protruded surface having a portion overlying the dummy metal line and projecting closer to said fuse than a portion between the dummy metal lines.

9. The semiconductor device according to claim 1, wherein
said fuse is formed from at least two portions different in width.

10. A semiconductor device formed on a substrate, comprising:
an interconnection line formed on said substrate and provided to structure a prescribed circuit; and
a fuse incorporated into said interconnection line,
said fuse having a width gradually reduced from an end toward an intermediate portion of said fuse.

11. The semiconductor device according to claim 10, wherein
said fuse has at least three different widths from the end toward the intermediate portion.
